(19) United States
(12) Patent Application Publication
(10) Pub. No.: US 2026/0096206 A1
(43) Pub. Date: Apr. 2, 2026

(54) INTER-NANORIBBON CONNECTIONS TO ENABLE SCALED CIRCUITS

(71) Applicant: Intel Corporation, Santa Clara, CA (US)

(72) Inventors: Abhishek Anil Sharma, Portland, OR (US); Wilfred Gomes, Portland, OR (US)

(21) Appl. No.: 18/899,386

(22) Filed: Sep. 27, 2024

(51) Int. Cl. H01L 27/118

(52) U.S. Cl. CPC H10D 84/907; H10D 84/953; H10D 84/975

(57) ABSTRACT

Embodiments herein relate to an interconnect architecture for a multi-transistor stack including channel structures in the form of nanoribbons or nanowires. In one aspect, a metal interconnect is routed between the transistors to provide between electrical connections for control gates and/or source/drain nodes of the transistors. The electrical connections can be provided between transistors in the same stack or in different stacks. In another aspect, control gates of transistors in a stack are independently controlled.

### BACKGROUND

There is a continuing goal to improve performance, size and power consumption in transistors. Designers have recently considered technologies such as nanoribbon transistors. These transistors have a number of thin silicon sheets as a channel material, with a surrounding gate, and provide advantages such as good electrostatic control, higher current drivability, small size, low power consumption, high speed, reduced gate length, and good performance at low applied voltage. However, many challenges remain in designing these semiconductor devices.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A depicts an example configuration of metal interconnects in a stacked structure 50 which includes four nanoribbons 51-54, a gate 57 and contacts 55 and 56 which are coupled to each nanoribbon, in accordance with various embodiments.

FIG. 1B depicts a cross-sectional view in a y-z plane of a transistor 100 having stacked channel structures 115, 120, 125 and 130 comprising at least one of nanoribbons or nanowires, consistent with FIG. 1A, in accordance with various embodiments.

FIG. 1C depicts a cross-sectional view in an x-z plane along the line 108 of the transistor 100 of FIG. 1B, where the stacked channel structures are nanoribbons, in accordance with various embodiments.

FIG. 1D depicts a cross-sectional view in an x-z plane along the line 108 of the transistor 100 of FIG. 1B, where the stacked channel structures are nanowires, in accordance with various embodiments.

FIG. 2A depicts an example configuration of metal interconnects in a stacked structure 60 which includes four nanoribbons 51-54, four gates 61-64, and a separate pair of contacts 65/66, 67/68, 69/70 and 71/72 coupled to each nanoribbon, in accordance with various embodiments.

FIG. 2B depicts a cross-sectional view of an example stacked structure 200 having first and second transistors 210 and 220, respectively, which each have two channel structures 115/120, and 125/130, respectively, consistent with FIG. 2A, in accordance with various embodiments.

FIG. 3 depicts a cross-sectional view of an example stacked structure 300 having first, second, third and fourth transistors 310, 320, 330 and 340, respectively, which each have one channel structure 115, 120, 125 and 130, respectively, consistent with FIG. 2A, in accordance with various embodiments.

FIG. 4A depicts an example configuration of metal interconnects in a stacked structure 80 which includes four nanoribbons 51-54, four gates 61-64, and a metal layer 81 between the nanoribbons 52 and 53, in accordance with various embodiments.

FIG. 4B depicts a cross-sectional view of an example stacked structure 400, where a metal layer 410 is provided between adjacent channel structures 120 and 125, consistent with FIG. 4A, in accordance with various embodiments.

FIG. 5A depicts an example configuration of a stacked structure 90 which includes n-type nanoribbons 51 and 52 and p-type nanoribbons 53′ and 54′ in the same stack, in accordance with various embodiments.

FIG. 5B depicts a cross-sectional view of an example stacked structure 500 which includes n-type and p-type channel structures 115/120, and 125/130, respectively, in transistors 510 and 520, respectively, consistent with FIG. 5A, in accordance with various embodiments.

FIG. 6 depicts an example configuration of metal interconnects in a stacked structure 600 which includes eight transistors in four levels, L1-L4, with one nanoribbon per level, in accordance with various embodiments.

FIG. 7 depicts an example configuration of metal interconnects in a stacked structure 700 which includes eight transistors in four levels, L1-L4, with two nanoribbons in the second level, L2, in accordance with various embodiments.

FIG. 8 depicts an example configuration of metal interconnects in a stacked structure 800 which includes ten transistors in five levels, L1-L5, with one nanoribbon per level, in accordance with various embodiments.

FIG. 9 depicts an example configuration of a stacked structure 900 which includes two of the stacked structures of FIG. 8, where the nanoribbons extend across each level, in accordance with various embodiments.

FIG. 10 depicts an example view in the x-y plane consistent with L4 in FIG. 6, in accordance with various embodiments.

FIG. 11 depicts a cross-sectional view of an example stacked structure 1100 consistent with FIG. 6, in accordance with various embodiments.

FIG. 12 depicts a cross-sectional view of an example stacked structure 1200 consistent with FIG. 7, in accordance with various embodiments.

FIG. 13 depicts a cross-sectional view of an example stacked structure 1300 consistent with FIG. 8, in accordance with various embodiments.

FIG. 14 depicts a cross-sectional view of an example stacked structure 1400 consistent with FIG. 9, in accordance with various embodiments.

FIG. 15 depicts a cross-sectional view of an example stacked structure 1500 which is similar to FIG. 14 but has a different metal interconnect 1590, in accordance with various embodiments.

FIG. 16 depicts a cross-sectional view of an example stacked structure 1600 which is similar to FIGS. 14 and 15 but has different metal interconnects 1690, 1691 and 1692, in accordance with various embodiments.

FIG. 17 depicts a cross-sectional view of another example stacked structure 1700, where a metal interconnect 1790 extends between offset stacks 1725 and 1750, in accordance with various embodiments.

FIG. 18 depicts a cross-sectional view of another example stacked structure 1800, in accordance with various embodiments.

FIG. 19 depicts a cross-sectional view of a layered semiconductor structure 1900 in which a stacked structure can be provided, in accordance with various embodiments.

FIG. 20 depicts a view of a stacked structure 2000, in which p-type and n-type channel structures are arranged laterally of one another in respective stacks, in accordance with various embodiments.

FIG. 21 depicts a view of a stacked structure 2100 in which p-type and n-type channel structures are arranged vertically in a stack, in accordance with various embodiments.

FIG. 22 illustrates an example of components that may be present in a computing system 2250 for implementing the techniques (e.g., operations, processes, methods, and methodologies) described herein.

### DETAILED DESCRIPTION

Various challenges are encountered in meeting the goals of improving performance, size and power consumption in transistors.

Nanoribbon transistors and related technologies have emerged as a possible solution. Nanoribbon transistors, also referred to as nanosheet transistors, have a number of thin silicon ribbons or sheets as a channel material, with a surrounding gate. The channel material can have other formats as well, such as a nanowire. The term nanochannel or nanostructure channel may include both nanoribbon and nanowire.

A nanoribbon is a two-dimensional nanostructure with thickness of about 1 to 100 nm, for example. Example materials include transition metal dichalcogenides (TMDs) such as Molybdenum disulfide (MoS2), Tungsten disulfide (WS2), and Tungsten Diselenide (WSe2), Bismuth Telluride (BiTe), and Graphene.

A nanowire is a nanostructure in the form of a wire with the diameter of tens of nanometers or less, for example. Example materials include silicon, Gallium arsenide (GaAs), Germanium, metal oxides such as In2O3, SnO2, and ZnO, Carbon, conductive metals such as gold and copper, and compound semiconductors such as gallium nitride.

A stacked semiconductor device can be formed which includes multiple levels of transistors arranged in a stack.

However, the placement of interconnects in the device is a challenge, as the interconnects increase the size of the device.

The solutions provided herein address the above and other disadvantages. In one aspect, an interconnect architecture is provided in which interconnects are routed between transistors in a multi-transistor stack, to provide electrical connections between control gates and/or source/drain nodes of the transistors. The electrical connections can be provided between transistors in a same column or in different columns of one or more stacks. In another aspect, control gates of adjacent transistors in the stack are independently controlled by providing an insulation region between adjacent control gates. The source/drain nodes of adjacent transistors in the stack can also be independently controlled by providing an insulation region between the source/drain nodes.

The solutions provide advantages such as reduced size and greater flexibility in configuring the connections between the transistors. For example, an interconnect within the stack can avoid the need for routing in top or bottom metal layers with the associated complexity.

In example implementations, different combinations of p-type and n-type channel structures with independent gate and contact connections can be used to make compact intellectual property (IP) blocks. An IP block can refer to, e.g., a reusable unit of logic, cell, or chip layout design which can be used as building block for various chip- and logic designs.

These and other features will be further apparent in view of the following discussion.

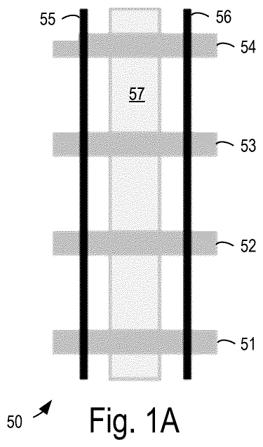

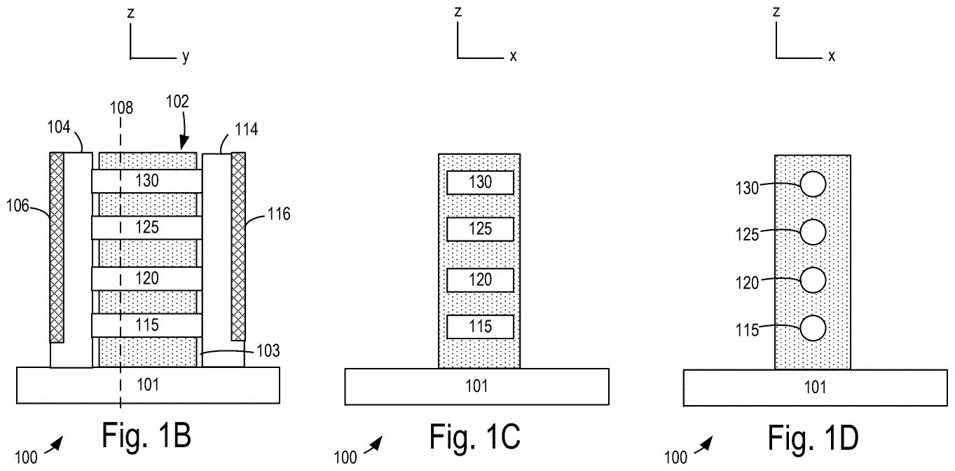

FIG. 1A depicts an example configuration of metal interconnects in a stacked structure 50 which includes four nanoribbons 51-54, a gate 57 and contacts 55 and 56 which are coupled to each nanoribbon, in accordance with various embodiments. The contacts are coupled to source/drain nodes on opposing sides of the gates, and the source/drain nodes are coupled to the nanoribbons. In this approach, a single transistor is formed.

FIG. 1B depicts a cross-sectional view in a y-z plane of a transistor 100 having stacked channel structures 115, 120, 125 and 130 comprising at least one of nanoribbons or nanowires, consistent with FIG. 1A, in accordance with various embodiments. The stacked channel structures are in a stack 102 which includes a gate 103 that surrounds each of the channel structures. The channel structures can be at least one of nanoribbons or nanowires, for instance, as mentioned. The stack may be formed on a substrate 101, where epitaxial silicon portions 104 and 114 extend up from the substrate. The epitaxial silicon portions 104 and 114 comprise doped/conductive silicon and act as S/D nodes of the transistor. As an example, the transistor can be a metal-oxide semiconductor field-effect transistor (MOSFET).

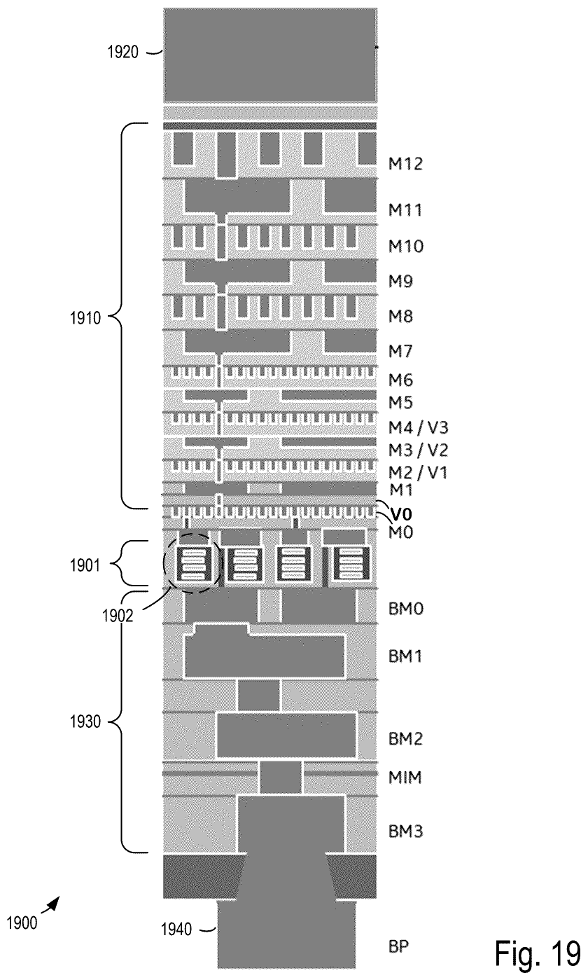

For an n-type or n-channel MOSFET (nMOSFET), the channel structures can comprise p-type silicon with doped n-type areas which form the source/drain nodes (S/D nodes). For a p-type or p-channel MOSFET (pMOSFET), the channel structures can comprise n-type silicon with doped p-type areas which form the S/D nodes. Metal contacts or interconnects 106 and 116 can be coupled to the epitaxial silicon portions 104 and 114, respectively, and routed higher to top metal layers of a layered semiconductor structure such as depicted in FIG. 19. Another option involves routing the metal contacts to a bottom or backside metal layer below the substrate.

The transistor 100 thus has four channel structures which extend between opposing S/D nodes, and a gate 103, which is insulated from the S/D nodes so that it can be separately controlled. When a voltage is applied to the gate which is sufficiently high, the transistor is turned on (becomes conductive) so that conductive channels are formed along the lengths of the channel structures, from one S/D node to the other. The transistor can be connected to other transistors to form a circuit such as a logic circuit which receives one or more input voltages and outputs one or more output voltages to perform a logic operation.

FIG. 1C depicts a cross-sectional view in an x-z plane along the line 108 of the transistor 100 of FIG. 1B, where the stacked channel structures are nanoribbons, in accordance with various embodiments. The nanoribbons have a generally rectangular cross section and have a width in the x direction which is much smaller than their length in the y direction.

FIG. 1D depicts a cross-sectional view in an x-z plane along the line 108 of the transistor 100 of FIG. 1B, where the stacked channel structures are nanowires, in accordance with various embodiments. The nano wires can have a generally circular cross section.

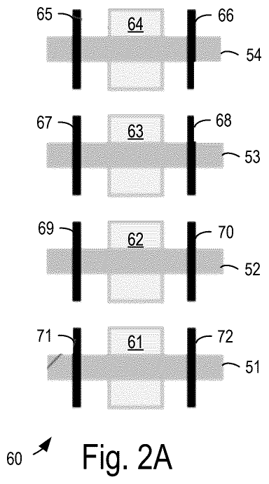

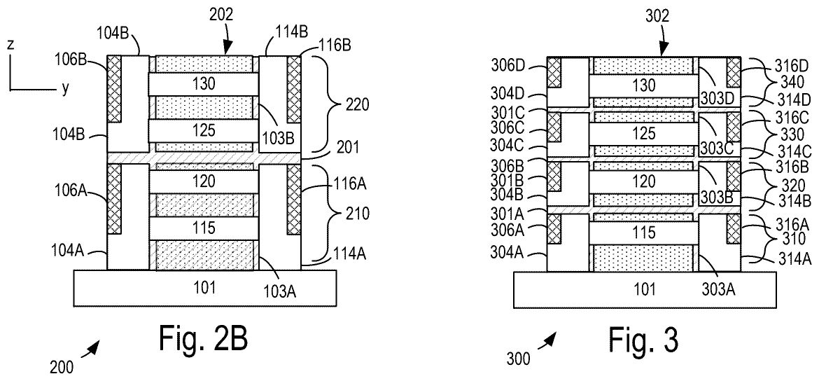

FIG. 2A depicts an example configuration of metal interconnects in a stacked structure 60 which includes four nanoribbons 51-54, four gates 61-64, and a separate pair of contacts 65/66, 67/68, 69/70 and 71/72 coupled to each nanoribbon, in accordance with various embodiments. This approach provide cuts or gaps in the contacts so that separate transistors can be formed.

FIG. 2B depicts a cross-sectional view of an example stacked structure 200 having first and second transistors 210 and 220, respectively, which each have two channel structures 115/120, and 125/130, respectively, consistent with FIG. 2A, in accordance with various embodiments. An insulator 201 is provided between the two transistors to allow them to operate independently. This example includes one gap in the contacts.

The stacked channel structures are in a stack 202 which includes a first gate 103A that surrounds first and second channel structures 115 and 120, respectively, and a second gate 103B that surrounds third and fourth channel structures 125 and 130, respectively. The first transistor can include epitaxial silicon portions 104A and 114A as S/D nodes, and the second transistor can include epitaxial silicon portions 104B and 114B as S/D nodes. The use of epitaxial silicon is an example as other materials such as non-epitaxial silicon could be used. For the first transistor 210, metal interconnects 106A and 116A can be coupled to the silicon portions 104A and 114A, respectively. For the second transistor 220, metal interconnects 106B and 116B can be coupled to the silicon portions 104B and 114B, respectively.

FIG. 3 depicts a cross-sectional view of an example stacked structure 300 having first, second, third and fourth transistors 310, 320, 330 and 340, respectively, which each have one channel structure 115, 120, 125 and 130, respectively, consistent with FIG. 2A, in accordance with various embodiments. Insulators 301A, 301B and 301C are provided between adjacent transistors 310/320, 320/330 and 330/340, respectively, to allow them to operate independently.

The stacked channel structures are in a stack 302 which includes a first gate 303A that surrounds the first channel structure 115, a second gate 303B that surrounds the second channel structure 120, a third gate 303C that surrounds the third channel structure 125, and a fourth gate 303D that surrounds the fourth channel structure 130.

The first transistor can include silicon portions 304A and 314A as S/D nodes, the second transistor can include silicon portions 304B and 314B as S/D nodes, the third transistor can include silicon portions 304C and 314C as S/D nodes, and the fourth transistor can include silicon portions 304D and 314D as S/D nodes.

For the first transistor 310, metal interconnects 306A and 316A can be coupled to the silicon portions 304A and 314A, respectively. For the second transistor 320, metal interconnects 306B and 316B can be coupled to the silicon portions 304B and 314B, respectively. For the third transistor 330, metal interconnects 306C and 316C can be coupled to the silicon portions 304C and 314C, respectively. For the fourth transistor 340, metal interconnects 306D and 316D can be coupled to the silicon portions 304D and 314D, respectively.

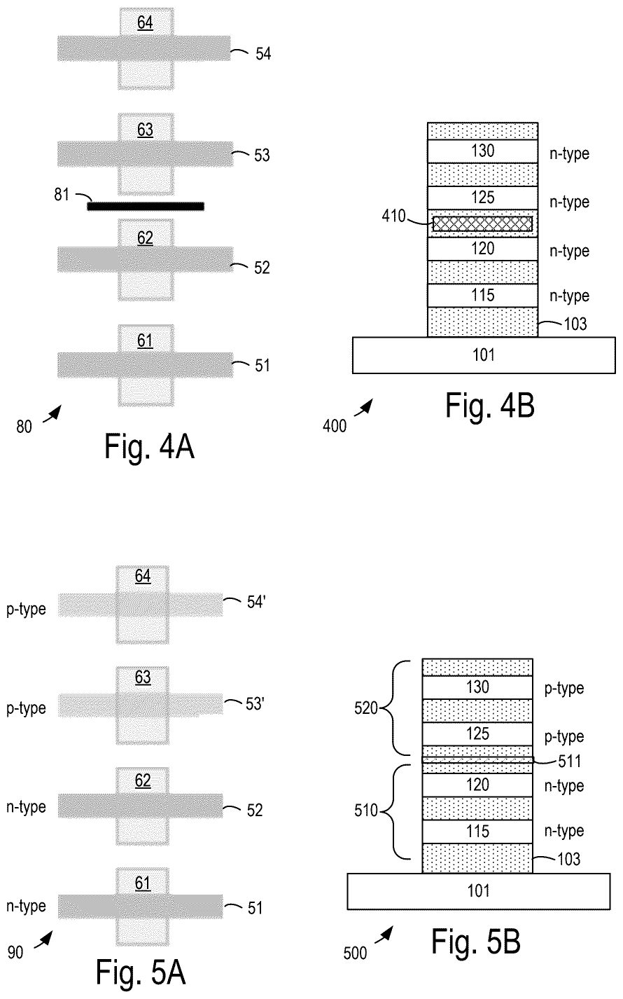

FIG. 4A depicts an example configuration of metal interconnects in a stacked structure 80 which includes four nanoribbons 51-54, four gates 61-64, and a metal layer 81 between the nanoribbons 52 and 53, in accordance with various embodiments. The metal layer represents an inter-nanoribbon contact which can extend to different parts of transistors, including the gates and the source/drain nodes.

FIG. 4B depicts a cross-sectional view of an example stacked structure 400, where a metal layer 410 is provided between adjacent channel structures 120 and 125, consistent with FIG. 4A, in accordance with various embodiments. The metal layer can be part of an interconnect that connects gate or S/D nodes of one or more transistors. By forming the metal layer on top of one or more underlying transistors and below one or more overlying transistors which are subsequently formed, space savings and flexibility in routing can be achieved. Various examples of metal interconnects are provided below. In this example, the channel structures are n-type so that an n-type transistor is formed.

FIG. 5A depicts an example configuration of a stacked structure 90 which includes n-type nanoribbons 51 and 52 and p-type nanoribbons 53′ and 54′ in the same stack, in accordance with various embodiments. This depicts the ability to mix channel types in a stack or column of transistors.

FIG. 5B depicts a cross-sectional view of an example stacked structure 500 which includes n-type and p-type channel structures 115/120, and 125/130, respectively, in transistors 510 and 520, respectively, consistent with FIG. 5A, in accordance with various embodiments. This example shows that both n-type and p-type transistors can be formed in the same stack. An insulator 511 is used to electrically isolate the gates of the two transistors. The S/D nodes are not shown here for simplicity.

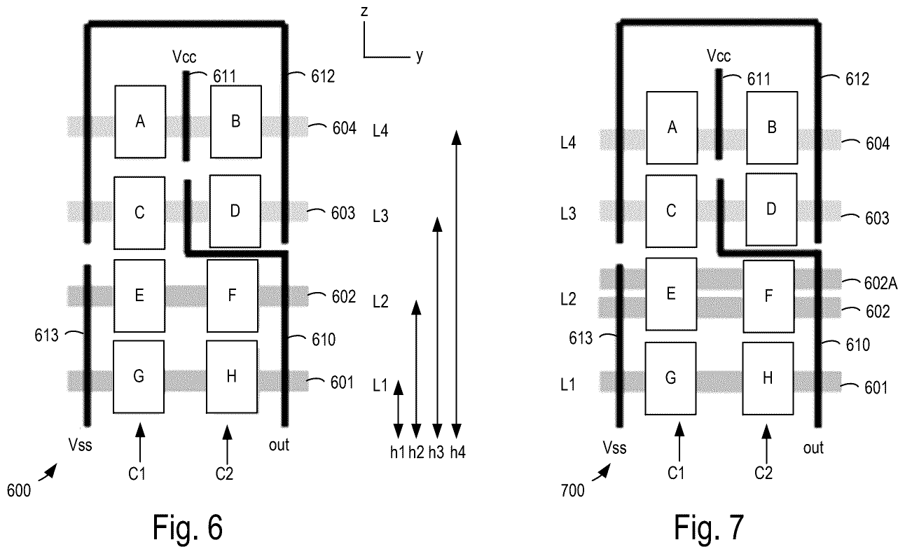

FIGS. 6-9 provide examples of a 2-2 AND-OR-invert circuit governed by an output=inversion of (AB+CD). This is one possible logic circuit, as many other are possible.

FIG. 6 depicts an example configuration of metal paths or interconnects in a stacked structure 600 which includes eight transistors in four levels, L1-L4, with one nanoribbon per level, in accordance with various embodiments. The four levels of transistors include transistors/control gates G and Hin L1, E and F in L2, C and D in L3, and A and B in L4. Each level has a nanoribbon which extends across the two transistors on the level so that it is a common, shared nanoribbon. For example, L1, L2, L3 and L4 have nanoribbons 601, 602, 603 and 604, respectively. Additionally, the transistors are arranged in two columns, C1 and C2.

A metal interconnect 613 couples Vss, a ground voltage, to the S/D nodes at the left side of E and G. A metal interconnect 612 couples the S/D nodes at the left side of A and C to the S/D nodes at the right side of B and D. A metal interconnect 611 couples a supply voltage Vcc to the S/D node between A and B. A metal interconnect 610 couples an output node to the S/D node between C and D, and the S/D nodes at the right side of F and H.

The metal interconnect 612 could be provided in the front side M0 layer, for example (FIG. 19).

Each level of transistors is at a different height above a substrate. For example, L1, L2, L3 and L4 can be at increasing heights h1, h2, h3 and h4, respectively.

Additionally, the nanoribbons can be of different types/polarities. For example, the nanoribbons 601 and 602 can be n-type and the nanoribbons 603 and 604 can be p-type.

FIG. 7 depicts an example configuration of metal interconnects in a stacked structure 700 which includes eight transistors in four levels, L1-L4, with two nanoribbons in the second level, L2, in accordance with various embodiments. The metal interconnects are the same as in FIG. 6. However, here, the transistors E and F have an additional n-type nanoribbon 602A which could help provide extra conductivity for these transistors. This example shows a multi-nanoribbon variant. The transistors are arranged in two columns, C1 and C2.

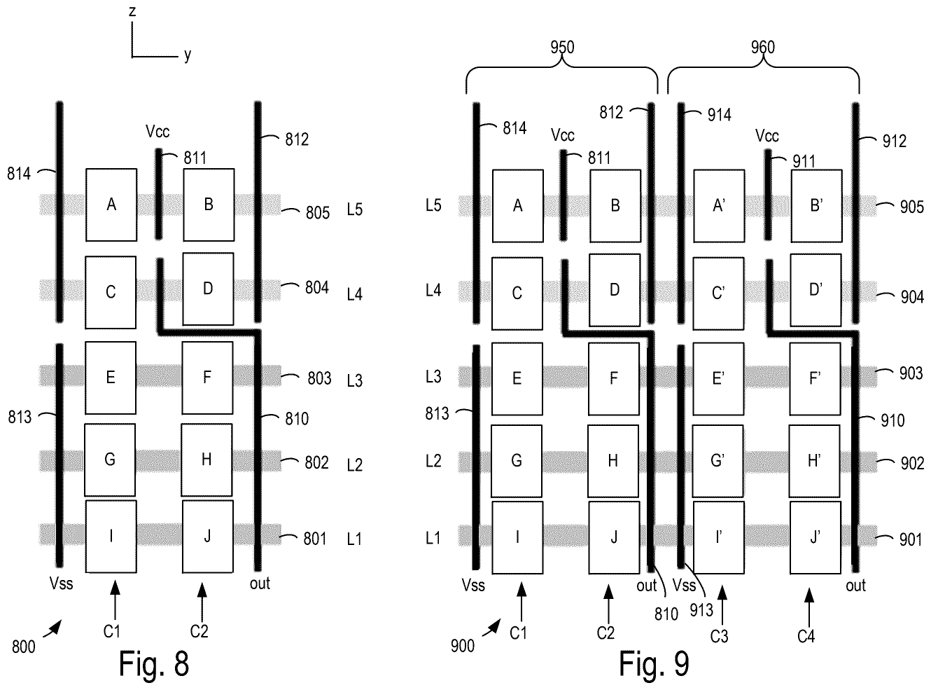

FIG. 8 depicts an example configuration of metal interconnects in a stacked structure 800 which includes ten transistors in five levels, L1-L5, with one nanoribbon per level, in accordance with various embodiments. The example of FIG. 6 is modified by adding an additional level with n-type transistors I and J. Additionally, separate metal interconnects are provided for A/C and B/D.

Specifically, the five levels of transistors include transistors I and J in L1, G and H in L2, E and F in L3, C and D in L4, and A and B in L5. Each level has a nanoribbon which extends across the two transistors on the level. For example, L1, L2, L3, L4 and L5 have nanoribbons 801, 802, 803, 804 and 805, respectively.

A metal interconnect 813 couples Vss to the S/D nodes at the left side of E, G and I. A metal interconnect 814 couples the S/D nodes at the left side of A and C to an external node. A metal interconnect 812 couples the S/D nodes at the right side of B and D to an external node. A metal interconnect 811 couples Vcc to the S/D nodes between A and B. A metal interconnect 810 couples an output node to the S/D node between C and D, and the S/D nodes at the right side of F, H and J.

The metal interconnects 812 and 814 could be provided in the front side M0 layer, for example (FIG. 19).

This example shows a multi-gate variant. The transistors are arranged in two columns, C1 and C2.

FIG. 9 depicts an example configuration of a stacked structure 900 which includes two of the stacked structures of FIG. 8, where the nanoribbons extend across each level, in accordance with various embodiments. First and second stacked structures 950 and 960, respectively, are depicted.

In the first stacked structure 950, the five levels of transistors include transistors I and J in L1, G and H in L2, E and F in L3, C and D in L4, and A and B in L5. Each level has a nanoribbon which extends across the two transistors on the level. For example, L1, L2, L3, L4 and L5 have nanoribbons 901, 902, 903, 904 and 905, respectively. The metal interconnects of FIG. 8 are also included.

In the second stacked structure 960, the five levels of transistors include transistors I′ and J′ in L1, G′ and H′ in L2, E′ and F′ in L3, C′ and D′ in L4, and A′ and B′ in L5. A metal interconnect 913 couples Vss to the S/D nodes at the left side of E′, G′ and I′. A metal interconnect 914 couples the S/D nodes at the left side of A′ and C′ to an external node. A metal interconnect 912 couples the S/D nodes at the right side of B′ and D′ to an external node. A metal interconnect 911 couples Vcc to the S/D nodes between A′ and B′. A metal interconnect 910 couples an output node to the S/D node between C′ and D′, and the S/D nodes at the right side of F′, H′ and J′.

This example shows a tiled variant. The transistors are arranged in four columns, C1, C2, C3 and C4.

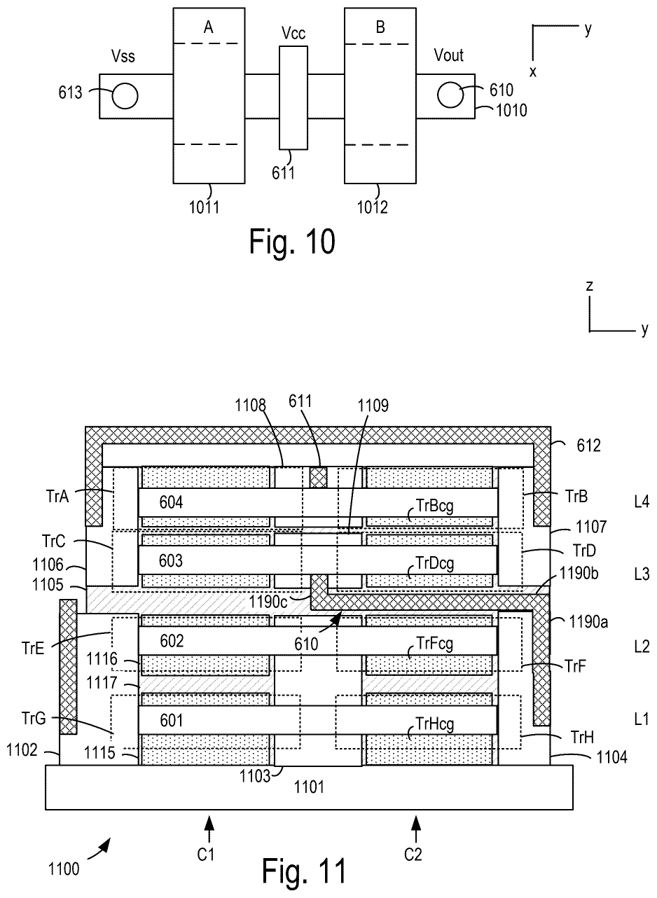

FIG. 10 depicts an example view in the x-y plane consistent with L4 in FIG. 6, in accordance with various embodiments. The metal interconnects 610 and 613 for Vout and Vss, respectively, are depicted as extending through a stack 1010 of nanoribbons. The metal interconnect 611 for Vcc, which represents a front side contact, is also depicted. The regions 1011 and 1012 correspond to the A and B transistors, respectively.

FIG. 11 depicts a cross-sectional view of an example stacked structure 1100 consistent with FIG. 6, in accordance with various embodiments. The structure includes transistors TrG and TrH in L1, TrE and TrF in L2, TrC and TrD in L3, and TrA and TrB in L4, all on a substrate 1101. Silicon regions 1102, 1103 and 1104 are S/D nodes for L1 and L2, and silicon regions 1106 and 1107 are outer S/D nodes for L3 and L4. Silicon region 1108 and 1109 are center S/D nodes for L4 and L3, respectively. Thus, in some cases, a S/D node is shared by adjacent levels of transistors and in other cases a S/D node is used just at one level.

Each transistor has a separate gate which can be independently controlled in this example due to the separation by insulation. For example, TrG and TrE have gates 1115 and 1116, respectively, separated by insulation 1117. The uses of a same fill pattern in the different shapes in the figures are meant to denote the same type of component. For example, a dotted pattern denotes a control gate, a diagonal slanted pattern denotes insulation, and a cross hatch pattern denotes a metal interconnect.

The transistors on each level in the different columns C1 and C2 share a channel structure such as a nanoribbon or nanoribbon. For example, channel structures 601, 602, 603 and 604 are provided in L1, L2, L3 and L4, respectively.

The metal interconnect 611 corresponds to same interconnect of FIG. 6, and provides Vcc to the silicon region 1108 at the source/drain of TrA and TrB. The metal interconnect 610 corresponds to the same interconnect of FIG. 6, and couples an output path to the silicon region 1109 at the source/drain of TrC and TrD. The interconnect 610 includes a portion 1190a which is coupled to the silicon region 1104, a horizontally extending portion 1190b which extends between TrD and TrF and their channel structures 603 and 602, respectively, and a vertically extending portion 1190c which extends to the silicon region 1109. The metal interconnect thus extends parallel to the substrate and then vertically away from the substrate to couple a first transistor to a second transistor.

In an example implementation, the stacked structure is an apparatus comprising a plurality of stacked channel structures 601-604 comprising at least one of nanoribbons or nanowires arranged in different levels L1-L4 of a stack 1100, one above the other; at one of the levels, e.g., L2 or L1, a first transistor TrF or TrH comprising a first channel structure 602 or 601 of the plurality of stacked channel structures, a control gate TrFcg or TrHcg which surrounds the first channel structure, and source/drain nodes 1103 and 1104; at another of the levels, e.g., L4 or L3, a second transistor TrB or TrD comprising a second channel structure 604 or 603 of the plurality of stacked channel structures, a control gate TrBcg or TrDcg which surrounds the second channel structure, and source/drain nodes 1108 and 1109; and a metal interconnect 610 which extends between the first and second levels to couple the first transistor to the second transistor.

Also, the metal interconnect extends parallel to the substrate in an insulation region 1105 between control gates of first and second transistors TrF/TfH and TrB/TrD.

In this example, one of the source/drain nodes 1104 of a first transistor is coupled to one of the source/drain nodes 1109 of a second transistor. In another possible option, one of the source/drain nodes of a first transistor is coupled to the gate of a second transistor.

The transistors are arranged in two columns, C1 and C2. The first and second transistors are in a same column in this example but, in other implementations, can be in different columns.

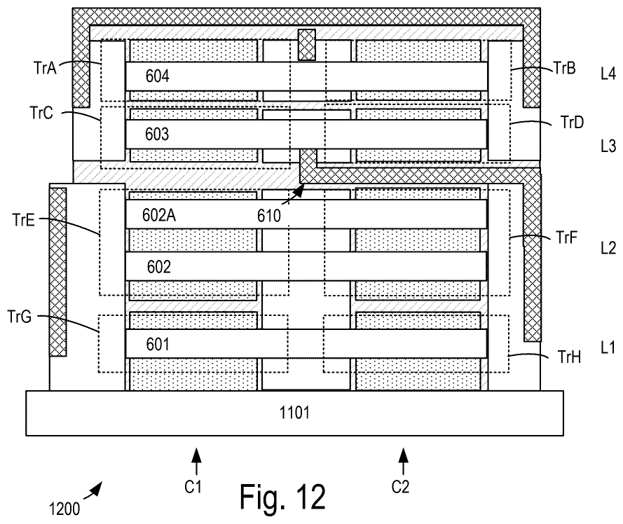

FIG. 12 depicts a cross-sectional view of an example stacked structure 1200 consistent with FIG. 7, in accordance with various embodiments. In this case, the transistors TrE and TrF at L2 include two channel structures 602 and 602A. The metal interconnect 610 as discussed in connection with FIG. 11 is also provided. The transistors are arranged in two columns, C1 and C2.

In this example, a first transistor, e.g., TrF, comprises a first number (2) of the plurality of stacked channel structures surrounded by its gate, and the second transistor, e.g., TrD, comprises a different second number (1) of the plurality of stacked channel structures surrounded by its gate. This provides flexibility is providing different current flows in different transistors which are coupled to one another.

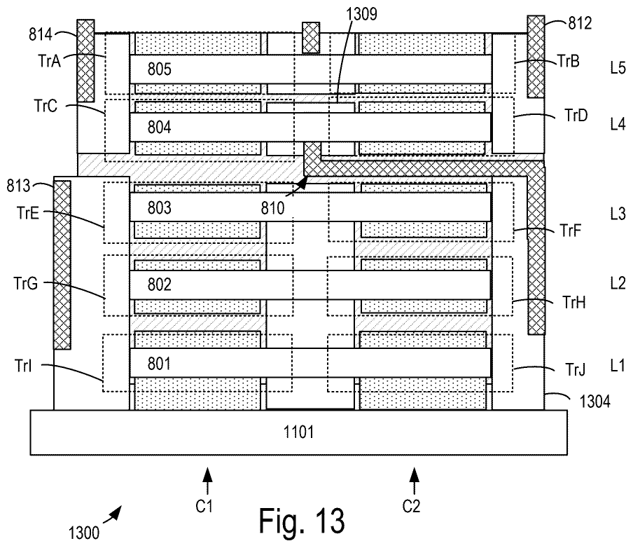

FIG. 13 depicts a cross-sectional view of an example stacked structure 1300 consistent with FIG. 8, in accordance with various embodiments. The structure includes transistors TrI and TrJ in L1, TrG and TrH in L2, TrE and TrF in L3, TrC and TrD in L3, and TrA and TrB in L5. The metal interconnects 10, 812, 813 and 814 of FIG. 8 are also shown. The metal interconnect 810 couples the silicon portion 1304 which is a S/D node of TrJ, TrH and TrF, to the silicon portion 1309 which is a shared S/D node for TrC and TrD. The transistors are arranged in two columns, C1 and C2.

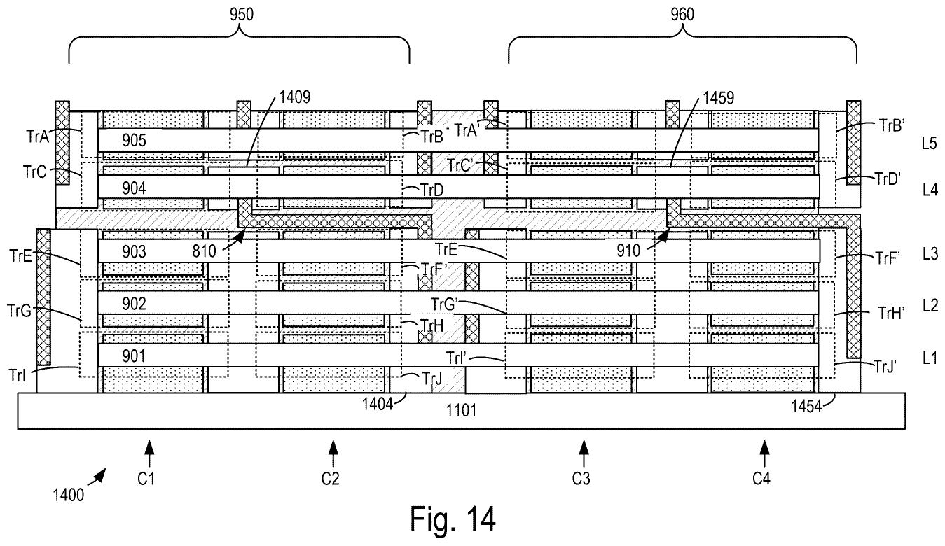

FIG. 14 depicts a cross-sectional view of an example stacked structure 1400 consistent with FIG. 9, in accordance with various embodiments. The first and second stacked structures 950 and 960, respectively, are depicted. In the stacked structure 950, the metal interconnect 810 couples the silicon portion 1404 which is a S/D node of TrJ, TrH and TrF to the silicon portion 1409 which is a S/D node for TrC and TrD. In the stacked structure 960, the metal interconnect 910 couples the silicon portion 1454 which is a S/D node of TrJ′, TrH′ and TrF′ to the silicon portion 1459 which is a shared S/D node for TrC′ and TrD′. The transistors are arranged in four columns, C1, C2, C3 and C4.

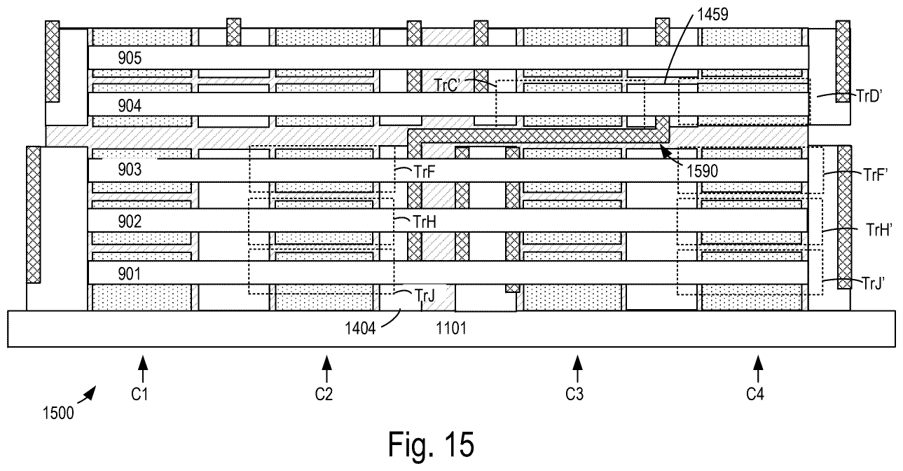

FIG. 15 depicts a cross-sectional view of an example stacked structure 1500 which is similar to FIG. 14 but has a different metal interconnect 1590, in accordance with various embodiments. In this case, the metal interconnect 1590 couples the silicon portion 1404 which is a S/D node of TrJ, TrH and TrF to the silicon portion 1459 which is a S/D node for TrC′ and TrD′. The transistors are arranged in four columns, C1, C2, C3 and C4.

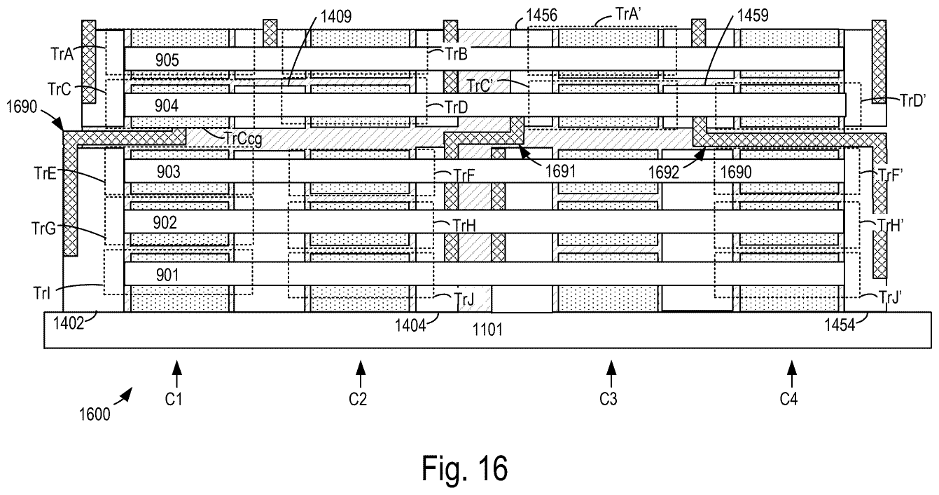

FIG. 16 depicts a cross-sectional view of an example stacked structure 1600 which is similar to FIGS. 14 and 15 but has different metal interconnects 1690, 1691 and 1692, in accordance with various embodiments. The metal interconnect 1690 couples the silicon portion 1402 which is a S/D node of TrI, TrG and TrE to the control gate TrCcg of the transistor TrC. The metal interconnect 1691 couples the silicon portion 1404 which is a S/D node of TrJ, TrH and TrF to the silicon portion 1456 which is a shared S/D node for TrC′ and TrA′. The metal interconnect 1692 couples the silicon portion 1454 which is a S/D node of TrJ′, TrH′ and TrF′ to the silicon portion 1459 which is a S/D node for TrC′ and TrD′. The transistors are arranged in four columns, C1, C2, C3 and C4.

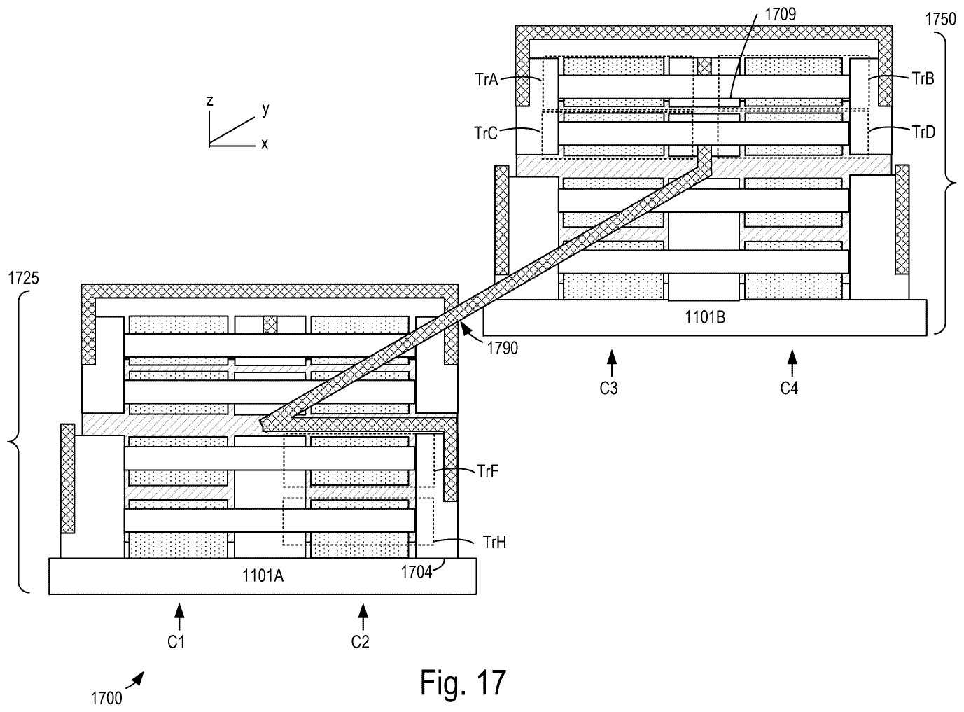

FIG. 17 depicts a cross-sectional view of another example stacked structure 1700, where a metal interconnect 1790 extends between offset stacks 1725 and 1750, in accordance with various embodiments. The stacks are offset in the y direction and do not share their channel structures. They have different channel structures. The offset stacks 1725 and 1750 are on substrate portions 1101A and 1101B of a common substrate in this example. The stacks are similar to the stack 1100 of FIG. 11 except the metal interconnect 1790 extends laterally between the stacks.

In particular, the metal interconnect 1790 couples a silicon portion 1704 which is a S/D node of TrF and TrH in the stack 1725 to the silicon portion 1709 which is a S/D node for TrC and TrD in the stack 1750. The transistors are arranged in four columns, C1 and C2 in the stack 1725, and C3 and C4 in the stack 1750.

This is an example of first and second transistors, e.g., TrF and TrD, that are in different stacks of transistors which do not share a channel structure, and that are coupled to one another by the metal interconnect 1790.

The above discussion provides many different examples of the use of one or more metal interconnects within a stack of transistors. Other implementations are possible.

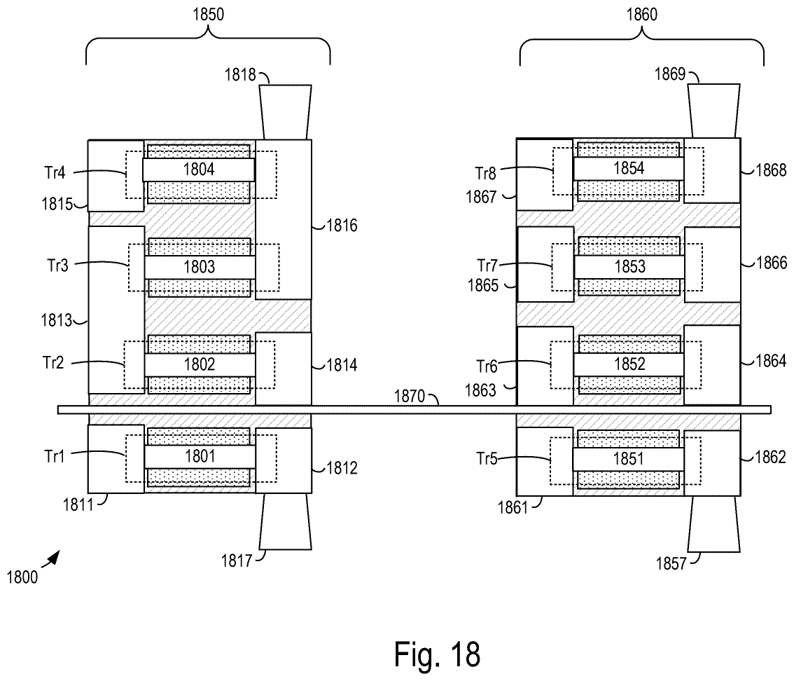

FIG. 18 depicts a cross-sectional view of another example stacked structure 1800, in accordance with various embodiments. The structure includes first and second stacks 1850 and 1860, respectively. The first stack includes transistors Tr1-Tr4 with channel structures 1801-1804, respectively, and the second stack includes transistors Tr5-Tr8 with channel structures 1851-1854, respectively.

In the first stack, the channel structures 1801 and 1803 are p-type and the channel structures 1802 and 1804 are n-type. Thus, p-type transistors Tr1 and Tr3 are provided along with n-type transistors Tr2 and Tr4. At the bottom, a contact 1817 is coupled to a silicon region 1812 which is a S/D node for the transistor Tr1. A silicon region 1811 is another S/D node for the transistor Tr1.

A diffusion layer 1870 separates the bottom transistor Tr1 from the other transistors in the stack. The transistor Tr2 includes S/D nodes 1813 and 1814, where the S/D node 1814 is shared to the transistor Tr3. A S/D node 1816 is also shared between the transistors Tr3 and Tr4, while a S/D node 1815 is just for the transistor Tr4. A top contact 1818 is coupled to the S/D node 1816.

In the second stack, the channel structure 1851 is p-type and the channel structures 1852, 1853 and 1854 are n-type. Thus, a p-type transistor Tr5 is provided along with n-type transistors Tr6, Tr7 and Tr8. At the bottom, a contact 1857 is coupled to a silicon region 1862 which is a S/D node for the transistor Tr5. A silicon region 1861 is another S/D node for the transistor Tr5.

The transistor Tr6 includes S/D nodes 1863 and 1864, the transistor Tr7 includes S/D nodes 1865 and 1866, and the transistor Tr8 includes S/D nodes 1867 and 1868. A top contact 1869 is coupled to the S/D node 1868.

FIG. 19 depicts a cross-sectional view of a layered semiconductor structure 1900 in which a stacked structure can be provided, in accordance with various embodiments. The stacked structures discussed herein can be provided using the layered semiconductor structure, in example implementations. The layered semiconductor structure includes an active/transistor region 1901 in which the stacked structures can be provided. An example transistor 1902 is depicted having four nanoribbons as channel structures. A number of vias and metal layer are provided above the active region including top metal layers M0-M12 and via layers V0-V3, in a top side region 1910. A carrier wafer is provided above the top side region.

A bottom side region 1930 includes a number of bottom metal (BM) layers, including BM0-BM3. A metal-insulator-metal (MIM) layer is also depicted between BM2 and BM3. A bottom bump metal layer 1940 is provided at the bottom of the bottom side region as a package interface.

The layered semiconductor structure can be formed by preparing the front side on a carrier layer 1920. The resulting structure is then inverted as shown. The backside can be prepared separately with structures to connect circuits in the active layer to the backside metal layers. The backside substrate is then inverted as shown and thinned, and attached to a backside of the front side substrate. The backside stack includes alternating dielectric and metal layers.

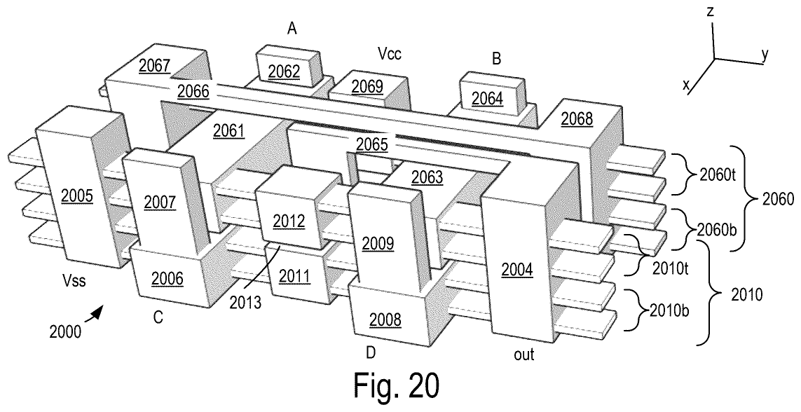

FIG. 20 depicts a view of a stacked structure 2000, in which p-type and n-type channel structures are arranged laterally of one another in respective stacks, in accordance with various embodiments. The structure includes a stack of four n-type nanoribbons 2010, including two top nanoribbons 2010t (at a top level) and two bottom nanoribbons 2010b (at a bottom level). The structure also includes a stack of four p-type nanoribbons 2060, including two top nanoribbons 2060t and two bottom nanoribbons 2060b. Transistors can be formed at the top and bottom levels. Silicon regions 2011 and 2012, which are separated by an insulation gap 2013, provide S/D nodes of the transistors associated with the bottom and top levels, respectively. Silicon regions 2004, 2005 and 2069 provide an output, a ground node (Vss), and a power supply (Vcc) node, respectively.

On the n-type side, a gate 2006 with interconnect 2007 is associated with a transistor C in the bottom level. A gate 2008 with interconnect 2009 is associated with a transistor D in the bottom level.

On the p-type side, a gate 2061 with interconnect 2062 is associated with a transistor A in the top level. A gate 2063 with interconnect 2064 is associated with a transistor B in the top level. A metal interconnect 2065 couples the silicon region 2004 to a metal layer, and a metal interconnect 2066 couples S/D nodes 2067 and 2068.

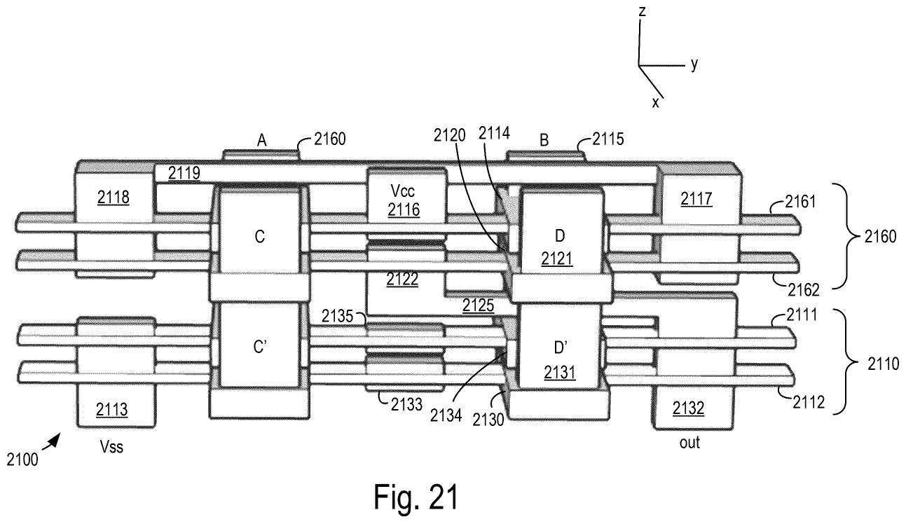

In this example, the stacked structure benefits from the use of separate S/D nodes on top of one another and separated by insulation, such as regions 2011 and 2012. However, it does not benefit from metal interconnects which extend between the transistors, as depicted in FIG. 21.

FIG. 21 depicts a view of a stacked structure 2100 in which p-type and n-type channel structures are arranged vertically in a stack, in accordance with various embodiments. The structure includes a stack of two n-type nanoribbons 2110 (nanoribbons 2111 and 2112) at a bottom or first level and stack of two p-type nanoribbons 2160 (nanoribbons 2161 and 2162) at a top or second level. A metal interconnect 2125 extends between the transistors and/or channel structures at the first and second levels, as discussed previously, to provide flexibility in connecting the transistors at the two levels or even within the same level.

Silicon regions 2112, 2113 and 2116 provide an output, a ground node (Vss), and a power supply node (Vcc), respectively. A transistor B is formed by a gate 2114 which extends around the nanoribbon 2161, and is coupled to an interconnect 2115. A S/D node 2116 on one side receives Vcc and a S/D node 2117 on an opposing side is coupled to another S/D node 2118 by an interconnect 2119.

A transistor D is formed by a gate 2120 which extends around the nanoribbon 2162, and is coupled to an interconnect 2121. A S/D node 2122 on one side is coupled to the interconnect 2125 and the S/D node 2117 is on the opposing side.

A transistor D′ is formed by a gate 2130 which extends around the nanoribbon 2112, and is coupled to an interconnect 2131. A S/D node 2132 on one side is an output node, while a S/D node 2133 is on the opposing side.

Another transistor B′ (under B) is formed by a gate 2134 which extends around the nanoribbon 2111, and is coupled to an interconnect on the side of the structure which is not shown. A S/D node 2132 is on one side and a S/D node 2135 is on the opposing side.

P-type transistors can similarly be formed at the areas denotes A and C and n-type transistors A′ (not shown) and C′ can be formed below them.

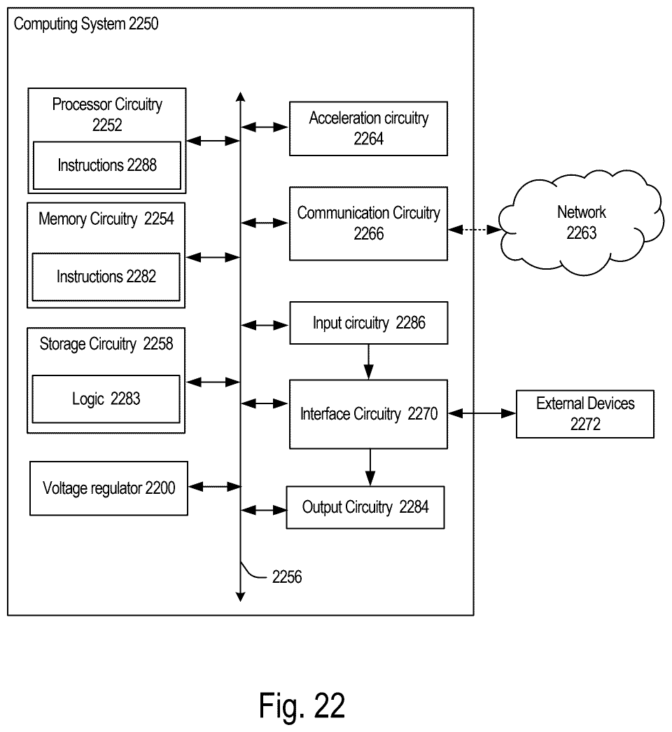

FIG. 22 illustrates an example of components that may be present in a computing system 2250 for implementing the techniques (e.g., operations, processes, methods, and methodologies) described herein.

The computing system 2250 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 2250, or as components otherwise incorporated within a chassis of a larger system.

The nanoribbon/nanowire structures described herein can be used in essentially any circuit, including the processor circuitry 2252, the memory circuitry 2254, the storage circuitry 2258 including the logic circuit 2258, the voltage regulator 2200, the acceleration circuitry 2264, the communication circuitry 2266, the input circuitry 2286, the interface circuitry 2270 and the output circuitry 2284.

In one approach, all or part of the computing system 2250 is provided in a SoP, System in Package (SiP) or a System on Chip (SoC).

The voltage regulator can provide a voltage Vout to one or more of the components of the computing system 2250. The memory circuitry 2254 may store instructions and the processor circuitry 2252 may execute the instructions to perform the functions described herein.

The system 2250 includes processor circuitry in the form of one or more processors 2252. The processor circuitry 2252 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 2252 may include one or more hardware accelerators (e.g., same or similar to acceleration circuitry 2264), which may be microprocessors, programmable processing devices (e.g., FPGA, ASIC, etc.), or the like. The one or more accelerators may include, for example, computer vision and/or deep learning accelerators. In some implementations, the processor circuitry 2252 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 2252 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 2252 may be coupled with or may include memory/storage and may be configured to execute instructions stored in the memory/storage to enable various applications or operating systems to run on the platform 2250. The processors (or cores) 2252 is configured to operate application software to provide a specific service to a user of the platform 2250. In some embodiments, the processor(s) 2252 may be a special-purpose processor(s)/controller(s) configured (or configurable) to operate according to the various embodiments herein.

As examples, the processor(s) 2252 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 2252 may be a part of a system on a chip (SoC), System-in-Package (SiP), a multi-chip package (MCP), and/or the like, in which the processor(s) 2252 and other components are formed into a single integrated circuit, or a single package, such as the Edison™ or Galileo™ SoC boards from Intel® Corporation. Other examples of the processor(s) 2252 are mentioned elsewhere in the present disclosure.

The system 2250 may include or be coupled to acceleration circuitry 2264, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 2264 may comprise logic blocks or logic fabric and other interconnected resources that may be programmed (configured) to perform various functions, such as the procedures, methods, functions, etc. of the various embodiments discussed herein. In such implementations, the acceleration circuitry 2264 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 2252 and/or acceleration circuitry 2264 may include hardware elements specifically tailored for machine learning and/or artificial intelligence (AI) functionality. In these implementations, the processor circuitry 2252 and/or acceleration circuitry 2264 may be, or may include, an AI engine chip that can run many different kinds of AI instruction sets once loaded with the appropriate weightings and training code. Additionally or alternatively, the processor circuitry 2252 and/or acceleration circuitry 2264 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®), Hardware 3 provided by Tesla®, Inc., an Epiphany™ based processor provided by Adapteva®, or the like. In some embodiments, the processor circuitry 2252 and/or acceleration circuitry 2264 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 2250 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 2250 also includes system memory 2254. Any number of memory devices may be used to provide for a given amount of system memory. As examples, the memory 2254 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 2254 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 2254 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 2258 provides persistent storage of information such as data, applications, operating systems and so forth. In an example, the storage 2258 may be implemented via a solid-state disk drive (SSDD) and/or high-speed electrically erasable memory (commonly referred to as “flash memory”). Other devices that may be used for the storage 2258 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 2254 and/or storage circuitry 2258 may also incorporate three-dimensional (3D) cross-point (XPOINT) memories from Intel® and Micron®.

The memory circuitry 2254 and/or storage circuitry 2258 is/are configured to store computational logic 2283 in the form of software, firmware, microcode, or hardware-level instructions to implement the techniques described herein. The computational logic 2283 may be employed to store working copies and/or permanent copies of programming instructions, or data to create the programming instructions, for the operation of various components of system 2250 (e.g., drivers, libraries, application programming interfaces (APIs), etc.), an operating system of system 2250, one or more applications, and/or for carrying out the embodiments discussed herein. The computational logic 2283 may be stored or loaded into memory circuitry 2254 as instructions 2282, or data to create the instructions 2282, which are then accessed for execution by the processor circuitry 2252 to carry out the functions described herein. The processor circuitry 2252 and/or the acceleration circuitry 2264 accesses the memory circuitry 2254 and/or the storage circuitry 2258 over the interconnect (IX) 2256. The instructions 2282 direct the processor circuitry 2252 to perform a specific sequence or flow of actions, for example, as described with respect to flowchart(s) and block diagram(s) of operations and functionality depicted previously. The various elements may be implemented by assembler instructions supported by processor circuitry 2252 or high-level languages that may be compiled into instructions 2288, or data to create the instructions 2288, to be executed by the processor circuitry 2252. The permanent copy of the programming instructions may be placed into persistent storage devices of storage circuitry 2258 in the factory or in the field through, for example, a distribution medium (not shown), through a communication interface (e.g., from a distribution server (not shown)), over-the-air (OTA), or any combination thereof.

The IX 2256 couples the processor 2252 to communication circuitry 2266 for communications with other devices, such as a remote server (not shown) and the like. The communication circuitry 2266 is a hardware element, or collection of hardware elements, used to communicate over one or more networks 2263 and/or with other devices. In one example, communication circuitry 2266 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 2266 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 2256 also couples the processor 2252 to interface circuitry 2270 that is used to connect system 2250 with one or more external devices 2272. The external devices 2272 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 2250, which are referred to as input circuitry 2286 and output circuitry 2284. The input circuitry 2286 and output circuitry 2284 include one or more user interfaces designed to enable user interaction with the platform 2250 and/or peripheral component interfaces designed to enable peripheral component interaction with the platform 2250. Input circuitry 2286 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 2284 may be included to show information or otherwise convey information, such as sensor readings, actuator position(s), or other like information. Data and/or graphics may be displayed on one or more user interface components of the output circuitry 2284. Output circuitry 2284 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 2250. The output circuitry 2284 may also include speakers and/or other audio emitting devices, printer(s), and/or the like. Additionally or alternatively, sensor(s) may be used as the input circuitry 2284 (e.g., an image capture device, motion capture device, or the like) and one or more actuators may be used as the output device circuitry 2284 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 2250 may communicate over the IX 2256. The IX 2256 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 2256 may be a proprietary bus, for example, used in a SoC based system.

The number, capability, and/or capacity of the elements of system 2250 may vary, depending on whether computing system 2250 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 2250 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.
Example 1 includes an apparatus, comprising: a plurality of stacked channel structures comprising at least one of nanoribbons or nanowires arranged in different levels of a stack one above the other; at one of the levels, a first transistor comprising a first channel structure of the plurality of stacked channel structures, a control gate which surrounds the first channel structure, and source/drain nodes; at another of the levels, a second transistor comprising a second channel structure of the plurality of stacked channel structures, a control gate which surrounds the second channel structure, and source/drain nodes; and a metal interconnect which extends between the first and second levels to couple the first transistor to the second transistor.
Example 2 includes the apparatus of Example 1, wherein the control gate of the first transistor is separate from the control gate of the second transistor.
Example 3 includes the apparatus of Example 1 or 2, wherein one of the source/drain nodes of the first transistor is coupled to the gate of the second transistor.
Example 4 includes the apparatus of Example 1 or 2, wherein one of the source/drain nodes of the first transistor is coupled to one of the source/drain nodes of the second transistor.
Example 5 includes the apparatus of any one of Examples 1-4, wherein the first and second transistors are in a same column of the stack.
Example 6 includes the apparatus of any one of Examples 1-4, wherein the first and second transistors are in different columns of the stack.
Example 7 includes the apparatus of any one of Examples 1-6, wherein the plurality of stacked channel structures are on a substrate, and the metal interconnect extends parallel to the substrate and then vertically away from the substrate to couple the first transistor to the second transistor.
Example 8 includes the apparatus of Example 7, wherein the metal interconnect extends parallel to the substrate in an insulation region between control gates of the first and second transistors.
Example 9 includes the apparatus of any one of Examples 1-8, wherein the first transistor comprises a first number of the plurality of stacked channel structures surrounded by its gate, and the second transistor comprises a different second number of the plurality of stacked channel structures surrounded by its gate.
Example 10 includes the apparatus of any one of Examples 1-9, wherein the plurality of stacked channel structures comprise at least one channel structure for an n-type transistor and at least one channel structure for a p-type transistor, in a same column of the stack.
Example 11 includes the apparatus of any one of Examples 1-10, wherein the plurality of stacked channel structures, the first transistor, the second transistor and the metal interconnect are provided in at least one of an integrated circuit, a System on Chip, a System in Package or a computing device.
Example 12 includes an apparatus, comprising: a plurality of transistors on a substrate in a stack, wherein the transistors are arranged in columns in different levels of the stack and comprise at least one of nanoribbons or nanowires; and a metal interconnect which extends between layers of the stack, and from one of the layers to another of the layers, to couple a first transistor of the plurality of transistors to a second transistor of the plurality of transistors.
Example 13 includes the apparatus of Example 12, wherein the first and second transistors are in a same column of the stack.
Example 14 includes the apparatus of Example 12, wherein the first and second transistors are in different columns of the stack.
Example 15 includes the apparatus of any one of Examples 12-14, wherein a source/drain node of the first transistor is coupled to a source/drain node of the second transistor.
Example 16 includes a circuit, comprising: a plurality of transistors; one or more inputs; and one or more outputs, wherein: the plurality of transistors comprise a first transistor at a first height above a substrate and a second transistor at a second height above the first height; the first and second transistors comprise control gates with at least one of nanoribbons or nanowires as a channel structure; a source/drain node of the second transistor is above a source/drain node of the first transistor; and a metal path extends between the source/drain nodes of the first and second transistors to couple the first transistor to the second transistor.
Example 17 includes the circuit of Example 16, wherein the first and second transistors are in different stacks of transistors have different channel structures.
Example 18 includes the circuit of Example 16 or 17, wherein the circuit is an AND-OR-invert circuit.
Example 19 includes the circuit of any one of Examples 16-18, wherein the metal path extends between the control gates of the first and second transistors.
Example 20 includes the circuit of Example 19, further comprising an insulation region between the control gates to insulate the metal path from the control gates.
Example 21 includes a method, comprising: receiving one or more input voltages at a circuit, and outputting one or more output voltages from the circuit to perform a logic operation, wherein the circuit is formed in a plurality of stacked channel structures comprising at least one of nanoribbons or nanowires arranged in different levels of a stack one above the other; at one of the levels, a first transistor comprises a first channel structure of the plurality of stacked channel structures, a control gate which surrounds the first channel structure, and source/drain nodes; at another of the levels, a second transistor comprises a second channel structure of the plurality of stacked channel structures, a control gate which surrounds the second channel structure, and source/drain nodes; and a metal interconnect extends between the first and second levels to couple the first transistor to the second transistor.
Example 22 includes the method of Example 21, wherein the control gate of the first transistor is independent of the control gate of the second transistor.
Example 23 includes the method of Example 21 or 22, wherein one of the source/drain nodes of the first transistor is coupled to the gate of the second transistor.
Example 24 includes the method of Example 21 or 22, wherein one of the source/drain nodes of the first transistor is coupled to one of the source/drain nodes of the second transistor.
Example 25 includes the method of any one of Examples 21-24, wherein the first and second transistors are in a same column of the stack.
Example 26 includes the method of any one of Examples 21-25, wherein the first and second transistors are in different columns of the stack.
Example 27 includes an apparatus, comprising means to perform the method of any one of Examples 21-26.
Example 28 includes a machine-readable storage including machine-readable instructions which, when executed, cause a computer to implement the method of any one of Examples 21-26.
Example 29 includes a computer program comprising instructions which, when executed by a computer, cause the computer to carry out the method of any one of Examples 21-26.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C”means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a plurality of stacked channel structures comprising at least one of nanoribbons or nanowires arranged in different levels of a stack one above the other;
at one of the levels, a first transistor comprising a first channel structure of the plurality of stacked channel structures, a control gate which surrounds the first channel structure, and source/drain nodes;
at another of the levels, a second transistor comprising a second channel structure of the plurality of stacked channel structures, a control gate which surrounds the second channel structure, and source/drain nodes; and
a metal interconnect which extends between the first and second levels to couple the first transistor to the second transistor.

2. The apparatus of claim 1, wherein the control gate of the first transistor is separate from the control gate of the second transistor.

3. The apparatus of claim 1, wherein one of the source/drain nodes of the first transistor is coupled to the gate of the second transistor.

4. The apparatus of claim 1, wherein one of the source/drain nodes of the first transistor is coupled to one of the source/drain nodes of the second transistor.

5. The apparatus of claim 1, wherein the first and second transistors are in a same column of the stack.

6. The apparatus of claim 1, wherein the first and second transistors are in different columns of the stack.

7. The apparatus of claim 1, wherein the plurality of stacked channel structures are on a substrate, and the metal interconnect extends parallel to the substrate and then vertically away from the substrate to couple the first transistor to the second transistor.

8. The apparatus of claim 7, wherein the metal interconnect extends parallel to the substrate in an insulation region between control gates of the first and second transistors.

9. The apparatus of claim 1, wherein the first transistor comprises a first number of the plurality of stacked channel structures surrounded by its gate, and the second transistor comprises a different second number of the plurality of stacked channel structures surrounded by its gate.

10. The apparatus of claim 1, wherein the plurality of stacked channel structures comprise at least one channel structure for an n-type transistor and at least one channel structure for a p-type transistor, in a same column of the stack.

11. The apparatus of claim 1, wherein the plurality of stacked channel structures, the first transistor, the second transistor and the metal interconnect are provided in at least one of an integrated circuit, a System on Chip, a System in Package or a computing device.

12. An apparatus, comprising:
a plurality of transistors on a substrate in a stack, wherein the transistors are arranged in columns in different levels of the stack and comprise at least one of nanoribbons or nanowires; and
a metal interconnect which extends between layers of the stack, and from one of the layers to another of the layers, to couple a first transistor of the plurality of transistors to a second transistor of the plurality of transistors.

13. The apparatus of claim 12, wherein the first and second transistors are in a same column of the stack.

14. The apparatus of claim 12, wherein the first and second transistors are in different columns of the stack.

15. The apparatus of claim 12, wherein a source/drain node of the first transistor is coupled to a source/drain node of the second transistor.

16. A circuit, comprising:
a plurality of transistors;
one or more inputs; and
one or more outputs, wherein:
the plurality of transistors comprise a first transistor at a first height above a substrate and a second transistor at a second height above the first height;
the first and second transistors comprise control gates with at least one of nanoribbons or nanowires as a channel structure;
a source/drain node of the second transistor is above a source/drain node of the first transistor; and
a metal path extends between the source/drain nodes of the first and second transistors to couple the first transistor to the second transistor.

17. The circuit of claim 16, wherein the first and second transistors are in different stacks of transistors having different channel structures.

18. The circuit of claim 16, wherein the circuit is an AND-OR-invert circuit.

19. The circuit of claim 16, wherein the metal path extends between the control gates of the first and second transistors.

20. The circuit of claim 19, further comprising an insulation region between the control gates to insulate the metal path from the control gates.
